(19) United States
(12) Patent Application Publication
(10) Pub. No.: US 2024/0105542 A1
(43) Pub. Date: Mar. 28, 2024

(54) POWER MODULE AND METHOD OF MANUFACTURING SAME

(71) Applicant: HYUNDAI MOBIS CO., LTD., Seoul (KR)

(72) Inventors: Jae Min HWANG, Yongin-si (KR); Seung Pyo LEE, Yongin-si (KR); Jae Guk AN, Yongin-si (KR); Tae Heun KIM, Yongin-si (KR)

(73) Assignee: HYUNDAI MOBIS CO., LTD., Seoul (KR)

(21) Appl. No.: 18/373,449

(22) Filed: Sep. 27, 2023

(30) Foreign Application Priority Data
Sep. 28, 2022 (KR) 10-2022-0122958

(51) Int. Cl. H01L 23/367; H01L 21/48

(52) U.S. Cl. CPC H01L 23/367; H01L 21/4882

(57) ABSTRACT

The present invention relates to a power module and a method of manufacturing the same. A power module according to one embodiment of the present invention includes a power module including a substrate a sealing member disposed to cover the substrate, a heatsink bonded to one surface of the substrate, a stepped bonding portion protruding to be stepped from one surface of the heatsink toward the substrate, and a bonding member disposed between and sinter-bonded to the stepped bonding portion and the substrate.

This application claims priority to and the benefit of Korean Patent Application No. 10-2022-0122958, filed on Sep. 28, 2022, the disclosure of which is incorporated herein by reference in its entirety.

### BACKGROUND

### 1. Field of the Invention

The present invention relates to a power module and a method of manufacturing the same, and more specifically, to a power module to which a heatsink is bonded through sinter-bonding and a method of manufacturing the same.

### 2. Discussion of Related Art

In general, a power module for supplying power to various electronic devices is mounted in a vehicle. In the power module, each power element is operated by an electrical signal, and heat is generated in each power element. A heatsink is provided to dissipate heat of the power module generated as described above.

In the conventional power module, a method of transferring heat to a heatsink through a thermal grease is applied, and a product to which a double-sided cooling type design is applied is being developed to secure heat dissipation performance.

However, as the power module using the double-sided cooling method was soldered twice, soldering quality problems such as a thickness failure and the like are increased, a material cost is high, and thus development of a power module using a single-sided cooling method has been proceeded. In this case, since the power module using the single-sided cooling method has lower cooling efficiency than the power module using the double-sided cooling method, there is a problem that sufficient heat dissipation performance may not be secured due to a low heat conductivity (2 to 4 W/mK) when heat is transferred using the thermal grease.

### SUMMARY OF THE INVENTION

The present invention is directed to providing a power module of which sufficient heat dissipation performance is secured through sinter-bonding between the power module and a heatsink for heat dissipation of the power module using a single-sided cooling method, and a method of manufacturing the same.

According to an aspect of the present invention, there is provided a power module including a substrate a sealing member disposed to cover the substrate, a heatsink bonded to one surface of the substrate, a stepped bonding portion protruding from one surface of the heatsink toward the substrate, and a bonding member disposed between and sinter-bonded to the stepped bonding portion and the substrate.

A bonding surface area of the stepped bonding portion may be smaller than a bonding surface area of the substrate.

A side surface of an edge of the stepped bonding portion may have a tolerance (d) with respect to an edge of the bonding surface of the substrate.

The bonding member may be a paste bonding member or a preform bonding member.

When the bonding member is the paste bonding member, the bonding member may be printed on the stepped bonding portion, and then a fixing solvent may be applied on the bonding member.

When the bonding member is the preform bonding member, the bonding member may be mounted on the stepped bonding portion.

The sealing member may include an epoxy molding compound (EMC).

According to another aspect of the present invention, there is provided a method of manufacturing a power module including forming a stepped bonding portion protruding from one surface of a heatsink to form a step, loading the heatsink, arranging a bonding member on the stepped bonding portion, loading a substrate, which is disposed to be covered by a sealing member, to come into contact with the bonding member, and sinter-bonding the bonding member.

The sinter-bonding includes pressing the sealing member by a press.

The press may have a contact surface area smaller than a contact surface area of the stepped bonding portion.

A buffer part may be disposed between the press and the sealing member.

The pressing may start at a sintering temperature of 130° C.

The bonding member may be a paste bonding member or a preform bonding member.

The bonding member is the paste bonding member, the bonding member may be printed on the stepped bonding portion, and then a fixing solvent may be applied on the bonding member.

The bonding member is the preform bonding member, a fixing solvent may be applied on the stepped bonding portion, the bonding member may be mounted on the fixing solvent, and then the fixing solvent may be applied on the bonding member.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a cross-sectional view illustrating a power module according to one embodiment of the present invention;

FIGS. 2 to 5 are views illustrating a process of manufacturing the power module according to one embodiment of the present invention;

FIG. 6 is a cross-sectional view illustrating a power module according to another embodiment of the present invention;

FIG. 7 is a plan view illustrating the power module according to another embodiment of the present invention; and

FIG. 8 is a perspective view illustrating a heatsink of the power module according to another embodiment of the present invention.

### DETAILED DESCRIPTION OF EXEMPLARY EMBODIMENTS

Since the present invention allows for various changes and numerous embodiments, specific embodiments will be illustrated in the accompanying drawings and described in the detailed description. However, this is not intended to limit the present invention to the specific embodiments, and it is to be appreciated that all changes, equivalents, and substitutes falling within the spirit and technical scope of the present invention are encompassed in the present invention. In the description of the embodiments, certain detailed descriptions of the related art are omitted when it is deemed that they may unnecessarily obscure the gist of the inventive concept.

While terms such as “first” and “second” may be used to describe various components, such components are not limited by the above terms. The above terms are used only to distinguish one component from another.

The terminology used herein is for the purpose of describing particular embodiments only and is not intended to limit the present invention. The singular forms are intended to include the plural forms, unless the context clearly indicates otherwise. In the present specification, it should be understood that the terms “comprise,” “comprising,” “include,” and/or “including,” when used herein, specify the presence of stated features, numbers, steps, operations, elements, components, and/or combinations thereof but do not preclude the presence or addition of one or more other features, numbers, steps, operations, elements, components, and/or combinations thereof.

In addition, throughout the specification, when “connected,” not only this means that two or more components are directly connected, but this also means that two or more components are indirectly connected through other components or are physically connected as well as electrically connected, or are one thing even referred to as different names according to positions or functions thereof.

Hereinafter, when a power module and a method of manufacturing the same according to the present invention will be described in detail with reference to the accompanying drawings, components that are the same or correspond to each other will be denoted by the same reference numeral, and redundant description will be omitted.

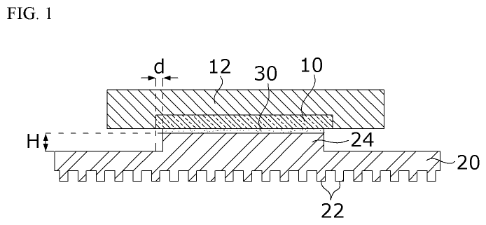

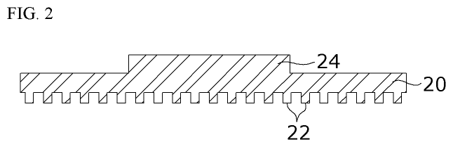

FIG. 1 is a cross-sectional view illustrating a power module according to one embodiment of the present invention, and FIGS. 2 to 5 are views illustrating a process of manufacturing the power module according to one embodiment of the present invention;

According to the drawings, the power module according to one embodiment of the present invention includes a substrate 10, a sealing member 12 disposed to cover the substrate 10, a heatsink 20 bonded to one surface of the substrate 10, a stepped bonding portion 24 protruding to be stepped from one surface of the heatsink 20 toward the substrate 10, and a bonding member 30 disposed between and sinter-bonded to the stepped bonding portion 24 and the substrate 10.

An active metal brazing (AMB) substrate may be applied as the substrate 10 to withstand a pressure generated during sinter-bonding. In addition, silicon nitride (Si₃N₄) or aluminum nitride (H—AlN) may be applied to a ceramic in the substrate 10. In addition, silver (Ag) plating using the same material as a sintered material may be applied to a surface treatment of the substrate 10, but the present invention is not limited thereto, and non-plating (Cu) or gold plating ((electroless nickel electroless palladium immersion gold (ENEPIG)) may be applied thereto.

The sealing member 12 may be disposed to cover one surface of the substrate 10. An epoxy molding compound (EMC) may be applied as the sealing member 12. The sealing member 12 may be disposed to cover an upper surface of the substrate 10, and the lower surface of the substrate 10 may be disposed to be coplanar with a surface of the sealing member 12.

The heatsink 20 may be bonded to the one surface of the substrate 10, that is, the lower surface of the substrate 10. The heatsink 20 is bonded to dissipate heat generated from the substrate 10, and a plurality of upright heat dissipation fins 22 are provided on the other surface opposite to one surface bonded to the substrate 10.

In the present embodiment, the heatsink 20 is not directly bonded to the one surface of the substrate 10 like the conventional case, but may be bonded thereto through a stepped bonding portion 24 which protrudes to be stepped from the one surface. The stepped bonding portion 24 is a portion which protrudes to be stepped toward the substrate 10 and may protrude in a thin rectangular parallelepiped shape like the heatsink 20.

The reason why the stepped bonding portion 24 is formed as described above is as follows. When the substrate 10 is in direct contact with the heatsink 20 during the sinter-bonding of the bonding member 30 which will be described below, delamination occurs at an interface between the substrate 10 and the sealing member 12, and thus heat dissipation performance can be degraded. Accordingly, in the present embodiment, the substrate 10 and the heatsink 20 are bonded through the stepped bonding portion 24. When the stepped bonding portion 24 is disposed between and bonded to the substrate 10 and the heatsink 20, a delamination phenomenon is fundamentally prevented because the interface between the substrate 10 and the sealing member 12 is not in direct contact with the heatsink 20.

Here, a height H of the stepped bonding portion 24 may be in the range of 0.5 to 2.0 mm but is not limited thereto. In addition, a bonding surface area of the stepped bonding portion 24 should be relatively smaller than a bonding surface area of the substrate 10. That is, when the bonding surface area of the stepped bonding portion 24 is larger than that of the substrate 10, a delamination phenomenon may occur because the interface between the substrate 10 and the sealing member 12 is in direct contact with the stepped bonding portion 24.

Accordingly, in the present embodiment, the bonding surface area of the stepped bonding portion 24 is designed as described above. In order to design as described above, a side surface of an edge of the stepped bonding portion 24 should be manufactured to form a tolerance d inward with respect to an edge of the bonding surface of the substrate 10. In this case, the tolerance d may be about 1 mm but is not limited thereto. The tolerance d may be set to be smaller after checking a tolerance of a component when heat dissipation performance of the power module is degraded.

The bonding member 30 is a member prepared for the sinter-bonding. The bonding member 30 may be pre-applied on the stepped bonding portion 24 and disposed between and sinter-bonded to the stepped bonding portion 24 and the substrate 10 which is pressed against the bonding member 30. The sinter-bonding is a method of bonding between target objects through diffusion bonding between particles at a lower temperature than a melting temperature and is performed through coarsening and densification between the particles by heating and pressurization. Since the sinter-bonding is bonding performed through metal diffusion bonding and does not form a separate intermetallic compound (IMC) layer, the sinter-bonding has an advantage in reliability compared to soldering.

Meanwhile, silver (Ag) or the like may be used as the bonding member 30, and copper (Cu) or the like may be used as the bonding member 30 to reduce a cost. In the present embodiment, a paste or preform type bonding member may be applied as the bonding member 30. A thickness of the bonding member 30 may be determined as a maximum thickness which satisfies heat dissipation performance without causing a maximum warpage of the substrate 10.

Hereinafter, a process of manufacturing the power module according to one embodiment of the present invention will be described. First, referring to FIG. 2, the stepped bonding portion 24 protruding to be stepped is formed on the one surface of the heatsink 20, and the heatsink 20 is loaded for bonding.

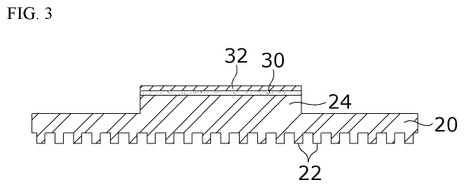

Referring to FIG. 3, the bonding member 30 is disposed on the stepped bonding portion 24. The paste or preform type bonding member may be applied as the bonding member 30, and the bonding member 30 illustrated in FIG. 3 is the paste type bonding member and may be printed on the stepped bonding portion 24. When the bonding member 30 is the paste type bonding member, a fixing solvent 32 may be applied on the stepped bonding portion 24 after the bonding member 30 is printed on the stepped bonding portion 24. The fixing solvent 32 is applied to fix a position of the substrate 10. When the bonding member 30 is the preform type bonding member, the bonding member 30 may be mounted on the fixing solvent 32 after the fixing solvent 32 is applied on the stepped bonding portion 24, and then, the fixing solvent 32 may be applied on the bonding member 30. In the case of the preform type bonding member, the fixing solvent 32 may be applied on both an upper surface and a lower surface of the bonding member 30 because a position of the bonding member 30 is also required to be fixed to the stepped bonding portion 24.

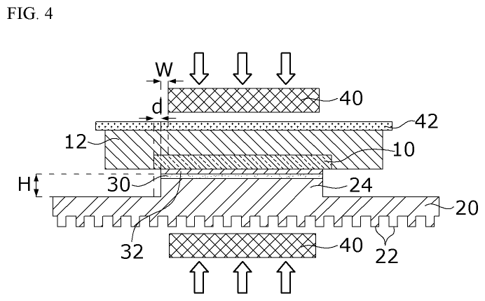

Referring to FIG. 4, after the substrate 10 is loaded, the sealing member 12 may be pressed by the press 40 from an upper side and a lower side. As described above, when the press 40 presses the sealing member 12, the sealing member 12 of the substrate 10 comes into contact with the stepped bonding portion 24 through the bonding member 30.

In this case, the press 40 may have a contact surface area relatively smaller than a contact surface area of the stepped bonding portion 24 so that the press 40 does not press an edge of the stepped bonding portion 24. That is, an edge of the press 40 may be smaller than the edge of the stepped bonding portion 24 by a width W.

In addition, a buffer part 42 may be disposed between the press 40 and the sealing member 12 in order to prevent the press 40 from coming into direct contact with the sealing member 12 and prevent warpage of the substrate 10 during the pressing of the press 40. The buffer part 42 serves to prevent cracks in or delamination of the sealing member 12 due to a sintering pressure when the press 40 comes into direct contact with the sealing member 12 and compensate for a pressure deviation due to the warpage of the substrate 10. A buffer film (such as a polytetrafluoroethylene (PTFE) material), a graphite sheet, or the like may be applied as the buffer part 42.

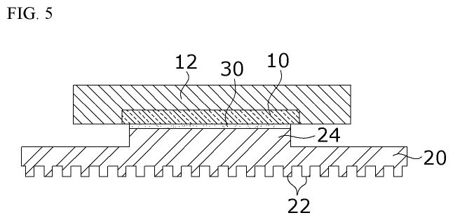

Referring to FIG. 5, the pressing of the press 40 during the sinter-bonding may start when a sintering temperature reaches 130° C. This is because, when the sintering temperature exceeds 140° C., self-sintering starts, and sinter-bonding strength decreases. In addition, this is because a nitrogen atmosphere is formed therein to prevent sintering oxidation in order to secure product quality during the sinter-bonding, and application of a condition in which warpage of the power module due to evaporation of the fixing solvent 32 does not occur is required during heating.

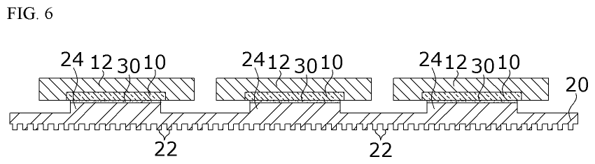

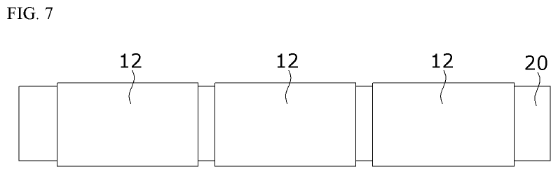

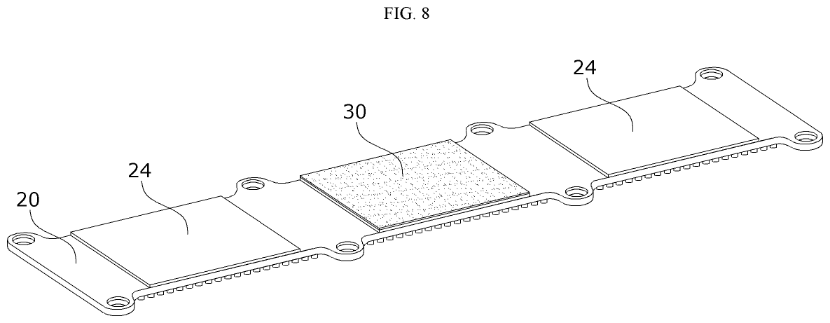

FIG. 6 is a cross-sectional view illustrating a power module according to another embodiment of the present invention, FIG. 7 is a plan view illustrating the power module according to another embodiment of the present invention, and FIG. 8 is a perspective view illustrating a heatsink of the power module according to another embodiment of the present invention.

Referring to the drawings, three substrates 10 may be bonded to a heatsink 20 as illustrated in the drawings. However, the number of substrates 10 is not limited to three, and a plurality of substrates 10, that is, two or more substrates 10, may be bonded thereto. To this end, a plurality of stepped bonding portions 24 may be formed on the heatsink 20 in a longitudinal direction.

As long as the plurality of stepped bonding portions 24 are formed on one heatsink 20 in the longitudinal direction as described above, the plurality of substrates 10 may be bonded thereto and used. FIG. 8 shows an example in which a bonding member 30 is printed on one stepped bonding portion 24 of the heatsink 20.

According to the power module according to one embodiment of the present invention described above, as the substrate 10 and the heatsink 20 are sinter-bonded (200 W/mK), a bonding surface having a superior conductivity can be secured compared to the conventional thermal grease (3 W/mK), and accordingly, the sinter-bonding can be applied to a power module using a single-sided cooling method. As a result, a soldering defect rate can be reduced compared to a power module using a double-sided cooling method and a material cost can be reduced compared to the power module using the double-sided cooling method.

According to embodiments of the present invention, sufficient heat dissipation performance can be secured through sinter-bonding between a power module and a heatsink for heat dissipation of the power module using a single-sided cooling method. In addition, since the single-sided cooling method can be applied to the power module, a soldering defect rate can be reduced and a material cost can be reduced compared to a power module using a double-sided cooling method.

While the present invention has been described above with reference to specific embodiments, it may be understood by those skilled in the art that various modifications and changes of the present invention may be made within a range not departing from the spirit and scope of the present invention defined by the appended claims.

What is claimed is:

1. A power module comprising:
a substrate;
a sealing member disposed to cover the substrate;
a heatsink bonded to one surface of the substrate;
a stepped bonding portion protruding from one surface of the heatsink toward the substrate; and
a bonding member disposed between and sinter-bonded to the stepped bonding portion and the substrate.

2. The power module of claim 1, wherein a bonding surface area of the stepped bonding portion is smaller than a bonding surface area of the substrate.

3. The power module of claim 2, wherein a side surface of an edge of the stepped bonding portion has a tolerance (d) with respect to an edge of a bonding surface of the substrate.

4. The power module of claim 1, wherein the bonding member includes a paste bonding member or a preform bonding member.

5. The power module of claim 4, wherein, when the bonding member includes the paste bonding member:
the bonding member is printed on the stepped bonding portion; and
then a fixing solvent is applied on the bonding member.

6. The power module of claim 4, wherein, when the bonding member includes the preform bonding member:
the bonding member is mounted on the stepped bonding portion.

7. The power module of claim 1, wherein the sealing member includes an epoxy molding compound (EMC).

8. A method of manufacturing a power module, comprising:
forming a stepped bonding portion protruding from one surface of a heatsink to forma step;
loading the heatsink;
arranging a bonding member on the stepped bonding portion;
loading a substrate, which is disposed to be covered by a sealing member, to come into contact with the bonding member; and
sinter-bonding the bonding member.

9. The method of claim 8, wherein the sinter-bonding includes pressing the sealing member by a press.

10. The method of claim 9, wherein the press has a contact surface area smaller than a contact surface area of the stepped bonding portion.

11. The method of claim 9, wherein a buffer part is disposed between the press and the sealing member.

12. The method of claim 9, wherein the pressing starts at a sintering temperature of 130° C.

13. The method of claim 8, wherein the bonding member includes a paste bonding member or a preform bonding member.

14. The method of claim 13, wherein the bonding member includes the paste bonding member;
the bonding member is printed on the stepped bonding portion; and
a fixing solvent is applied on the bonding member.

15. The method of claim 13, wherein the bonding member includes the preform bonding member;
a fixing solvent is applied on the stepped bonding portion;
the bonding member is mounted on the fixing solvent; and
the fixing solvent is applied on the bonding member.
